(19) United States
(12) Patent Application Publication
(10) Pub. No.: US 2012/0006097 A1
(43) Pub. Date: Jan. 12, 2012

(54) METHOD AND APPARATUS FOR MONITORING GAS CONCENTRATION

(75) Inventors: Mark Anthony Steele Henson, Stafford (GB); Matthew Paul Hills, Stafford (GB)

(73) Assignee: Environmental Monitoring and Control Limited, Stafford (GB)

(21) Appl. No.: 13/139,177

(22) PCT Filed: Dec. 10, 2009
(86) PCT No.: PCT/GB2009/002856

§ 371 Date: Sep. 28, 2011

(30) Foreign Application Priority Data
Dec. 12, 2008 (GB) 0822734.0

(51) Int. Cl. G01N 9/00; H05K 13/00; G01N 25/00

(52) U.S. Cl. 73/25.01; 29/592.1

(57) ABSTRACT

The method and apparatus are intended for monitoring the concentration of a gas in a fluid medium, such as in a liquid or gas medium. In a probe for measuring the temperature and gas concentration in the fluid medium, a gas concentration sensor comprising first and second electrodes is supported at a probe end of a tubular support. The probe end, in use, contacts the fluid medium. A thermocouple comprising a thermocouple junction and two thermocouple wires extends within the tubular support and the first electrode of the gas concentration sensor is electrically connected to the thermocouple. In the method for monitoring gas concentration, the gas concentration is measured by monitoring a voltage between at least one of the thermocouple wires and the second electrode.

The invention relates to a method and an apparatus for monitoring the concentration of a gas, in particular the concentration of a gas in a fluid medium, such as a gaseous or liquid medium. The invention also relates to the monitoring of the temperature of the fluid medium.

A conventional apparatus for monitoring the temperature of a fluid medium such as a molten metal comprises a thermocouple housed within a blind-ended tube. The thermocouple tip, or thermocouple junction, is located near the blind end of the tube and two thermocouple wires extend along the length of the tube. The tube, or sheath, is typically of a metal, such as steel, and is approximately 3 mm in outside diameter. Within the tube, the thermocouple wires are surrounded and separated by a compressed, non-conducting mineral powder to provide electrical insulation between the thermocouple wires, and between the wires and the tube. At the end of the tube opposite the blind end, the tube and the ends of the thermocouple wires are connected to a thermocouple compensating cable which extends from the end of the tube to allow connection to a monitoring apparatus. The end of the tube is typically sealed with an electrically-insulating and gas-tight seal in order to protect the thermocouple components within the tube.

Known probes and sensors for measuring the concentration of gas dissolved in fluid media are described in documents such as published patent applications WO2004/025289, WO2006/037992, WO2007/042805 and WO2007/042808, all of which are incorporated herein by reference, in their entirety. These documents describe sensors for the determination of hydrogen concentration in fluid media at elevated temperatures. This type of sensor consists of a proton-conducting solid electrolyte in contact with a metal/hydrogen reference standard, which is contained within a sealed chamber on one side of the solid electrolyte. Electrodes are positioned, or coated, on opposite faces of the solid electrolyte, one face of the electrolyte being exposed to the reference standard and the other side, outside the sealed chamber, being exposed to a hydrogen concentration to be measured. Similar probes may be constructed for the measurement of other gases, such as oxygen. In that case, an oxygen reference standard and an oxygen-ion-conducting solid electrolyte would be used, as would be understood by the skilled person.

A sensor of this type may be implemented in various convenient geometries, as described in WO2006/037992. In particular, the sensor may conveniently be packaged within a ceramic tube, hermetically sealed at one end and sealed with a solid electrolyte at the other end, and containing the reference standard. A first electrode is positioned on the surface of the solid electrolyte within the sealed tube, or chamber, and an electrical connection is made from the electrode to a metal stub, or contact, extending through the hermetic seal. A convenient connection can then be made to the contact, to monitor the voltage at the first electrode. A second electrode is positioned on the outer surface of the solid electrolyte, and an electrical connection can be made to this electrode in any convenient manner.

A sensor of this type may conveniently be mounted at an end of a suitable support, as described in WO2006/037992, to form a probe. The end of the probe carrying the sensor may then be immersed in a fluid medium, for example, at high temperature, in order to measure gas concentration within the fluid medium.

### SUMMARY OF INVENTION

The invention provides a probe, a method for fabricating a probe, a method for monitoring temperature and gas concentration in a fluid medium, and a measurement apparatus, as defined in the appended independent claims, to which reference should now be made. Preferred or advantageous features of the invention are set out in dependent sub-claims.

In a first aspect, the invention may therefore provide a probe for measuring the temperature and gas concentration in a fluid medium, usually at elevated temperature, such as a molten metal. The probe comprises a tubular support, a probe end of the support being suitable for immersion, in use, into or beneath the surface of a fluid medium. A thermocouple junction of a thermocouple is positioned at or close to the probe end of the support, such that it can equilibrate with the temperature of the fluid medium when the probe end of the support, containing the thermocouple junction, is placed in the medium. Two thermocouple wires extend from the thermocouple junction within the tubular support. The end of the tubular support remote from the probe end may terminate at a suitable support apparatus enabling physical handling of the probe during use and electrical connection to the thermocouple wires. A gas concentration sensor comprising first and second electrodes is supported at the probe end of the tubular support and the first electrode is electrically connected to the thermocouple. This advantageously enables at least one of the thermocouple wires to be used for electrical monitoring of the first electrode during gas concentration measurement.

During use, gas concentration measurement is achieved by monitoring the voltage between the first and second electrodes of the gas concentration sensor. An electrical connection to the second electrode may be achieved in any convenient manner. For example, a separate electrical wire, or conductor, may lead from the second electrode to the support apparatus, or a connection may be made through the fluid medium itself if it is a sufficiently good electrical conductor. In a preferred embodiment, however, the tubular support is electrically conducting and the second electrode is electrically connected to the tubular support. The voltage between the first and second electrode can then be monitored by monitoring the voltage between the tubular support and at least one of the thermocouple wires.

A suitable sensor may be of the type described above, in which the first and second electrodes are separated by a solid electrolyte, one electrode being exposed, in use, to a gas concentration to be measured and the second electrode being exposed, in use, to a reference gas concentration or a reference material. Either the first or second electrode, and the corresponding face of the solid electrolyte, may be exposed to the gas concentration to be measured, or vice versa.

The first electrode may be electrically connected to one of the thermocouple wires, above the thermocouple junction, and that wire is then preferably used for monitoring the voltage on the first electrode. In a preferred embodiment, however, the first electrode is electrically connected to the thermocouple junction. In this embodiment, either of the thermocouple wires may be used to monitor the voltage on the first electrode or both of the thermocouple wires may be used.

In the various embodiments described above, the electrical connection to the thermocouple may be made in any convenient manner, by means of a crimped connection or by welding, brazing or soldering.

It may be necessary to account for or compensate for a thermoelectric voltage generated along whichever thermocouple wire is used to monitor the sensor voltage. This is because such a thermoelectric voltage may effectively be superimposed on the sensor voltage during measurement. The thermocouple voltage can be measured prior to measurement of the sensor voltage and the measurement temperature may be determined. The sensor voltage can then be compensated either on the basis of the measured thermocouple voltage or using a value from a predetermined look-up table or calibration curve based on the measured thermocouple voltage or the temperature.

In an alternative embodiment, the electrical connection to the second sensor electrode may be fabricated from the same material as one of the thermocouple wires. In this case, automatic compensation for the thermocouple voltage at the measurement temperature may be achieved, by selecting as the connection to the first electrode the thermocouple wire made from the same material as the second sensor electrode wire.

In use, the probe end of the tubular support may be exposed to the gas concentration in the fluid medium, and it may be advantageous to prevent the gas from diffusing, or flowing, within the tubular support. A gas-tight plug may therefore be positioned in the tubular support, preferably near the probe end. This may conveniently be achieved by inserting a plug of a suitable powder, such as a suitable glass powder, into the tubular support and heating it to melt the powder and form the plug.

In a further aspect of the invention, a cap is secured at the probe end of the tubular support, enclosing and helping to support the gas concentration sensor. The cap may be of the same cross sectional shape as the tubular support, which may typically be circular. The cap may also have a closed end such that, when it is in place, the end of the probe is closed and may thus be protected against damage. It is necessary, however, for the gas in the molten metal to flow, or diffuse, towards the gas concentration sensor, in order to allow a gas concentration measurement to be made. The cap should therefore be perforated, or porous, to allow the diffusion of the gas. In one embodiment, the cap may be a metal cap, such as a steel cap. Alternatively, the cap may be a ceramic material; this may provide improved chemical resistance to the molten metal. In either case, at least a portion of the cap must be perforated, or porous, to allow the diffusion of gas. In one embodiment, the cap may be fabricated from more than one component, such as a non-porous metal or ceramic sleeve and a porous tip, closing the end of the sleeve. The porous tip may be of porous graphite or any other suitable material. In practice, any portion of the cap may be porous or perforated.

The tubular support may conveniently be fabricated from a metal, such as steel, to provide a low-cost, robust support structure. Similarly, the cap may comprise a metal, such as steel. Depending on the materials from which these components are made, and the fluid medium in which the probe is to be used, the components of the probe may need to be coated in order to prevent chemical attack by the fluid medium. For example, steel may be plasma-coated in order to reduce chemical attack by molten aluminium, as in conventional thermocouple probes.

A further aspect of the invention relates to a method for fabricating a probe for measuring the temperature and gas concentration in a fluid medium. The method may thus comprise the steps of electrically connecting a first electrode of a gas concentration sensor comprising first and second electrodes to a thermocouple comprising a thermocouple junction and two thermocouple wires extending within a tubular support, and supporting the sensor at a probe end of the tubular support. The resulting structure may then provide the advantages discussed above.

Advantageously, the tubular support and the thermocouple extending within the support may be based on a conventional thermocouple probe, or thermocouple apparatus. This comprises a thermocouple extending within a blind-ended tube, the thermocouple junction being positioned near the end of the tube. The tube is typically packed with an insulating powder, to prevent electrical contact between the thermocouple wires, or between the thermocouple wires and the blind-ended tube. In order to implement this aspect of the invention, the blind end of the tube is removed, exposing the thermocouple junction. The first electrode of the gas concentration sensor may then be electrically connected to the thermocouple junction, or to one of the thermocouple wires, and the gas concentration sensor supported at the end of the resulting tubular support.

As described above, a cap may then be secured to the end of the tubular support, enclosing the sensor. The cap may be secured to the tubular support in any convenient manner. If both components are of metal, they may be fastened together by brazing or welding, such as TIG welding. If the cap is of a ceramic material and the tubular support is metallic, then the components may be secured together using a suitable glass or other material.

In all aspects of the invention, electrical connections and seals should preferably be implemented such that their integrity is not affected at the temperature of the fluid medium in which the probe is to be used.

Other features of this aspect of the invention, relating to a method for fabricating a probe, are discussed above, or are set out in the appended claims.

A further aspect of the invention provides a method for monitoring temperature and gas concentration in a fluid medium using a probe as described above. This aspect of the invention relates to the use of the thermocouple wires in order to monitor the voltage at the first electrode of the gas concentration sensor. If the first electrode is electrically connected to one of the thermocouple wires, then that wire may be used to monitor to voltage. Alternatively, if the first electrode is electrically connected to the thermocouple junction, then either thermocouple wire may be used.

As described above, the end of the tubular support remote from the probe end may terminate at a suitable support apparatus for enabling physical handling of the probe and electrical connection to the probe. Thus, a measurement apparatus may be electrically connected by means of the support apparatus to each thermocouple wire and to the second electrode of the gas concentration sensor. In order to measure the temperature at the probe end, the measurement apparatus can monitor the voltage between the thermocouple wires, as in a conventional thermocouple probe. In order to measure the voltage between the first and second electrodes of the gas concentration sensor, the measurement apparatus may measure the voltage between a thermocouple wire and the second electrode.

A further aspect of the invention provides the measurement apparatus suitable for carrying out these operations.

As described, these various aspects of the invention may advantageously enable a robust and convenient probe for measuring both temperature and gas concentration in a fluid medium, advantageously taking both measurements from the same region within the fluid medium, such that the temperature and gas concentration measurements may be correlated with each other. This may advantageously enable reduction of errors arising from different portions of a fluid medium having different temperatures or different gas concentrations. Further, the probe may be convenient to operate and readings may easily be taken from a single measurement apparatus. In addition, the preferred method of fabricating the probe, by modifying a conventional thermocouple probe, may advantageously reduce costs and improve compatibility between existing probes and probes embodying the invention. Probes embodying the invention may also, however, be fabricated directly, without using the method of modifying a conventional thermocouple probe.

Aspects of the invention may be used in a wide variety of applications, including but not limited to measurement of hydrogen or oxygen concentrations in various fluid media. Examples include; monitoring oxygen supply in fuel cell applications, such as for solid oxide fuel cells (SOFC), monitoring of internal hydrogen reforming and monitoring hydrogen fuel utilisation; oxygen measurement for combustion control; oxygen measurement in materials processing, such as in ceramic processing, sintering and annealing; oxygen measurement and control in glassmaking, including for example control of furnace atmosphere and the oxygen potential of glass itself; other applications such as gas blending, gas purity measurement and research and development applications.

### SPECIFIC DESCRIPTION OF PREFERRED EMBODIMENTS AND BEST MODE OF THE INVENTION

FIG. 1 is a side view of a probe according to a first embodiment of the invention;

FIG. 2 is a perspective view of the tip of a probe according to the first embodiment;

FIG. 3 is an exploded perspective view of the probe tip of FIG. 2;

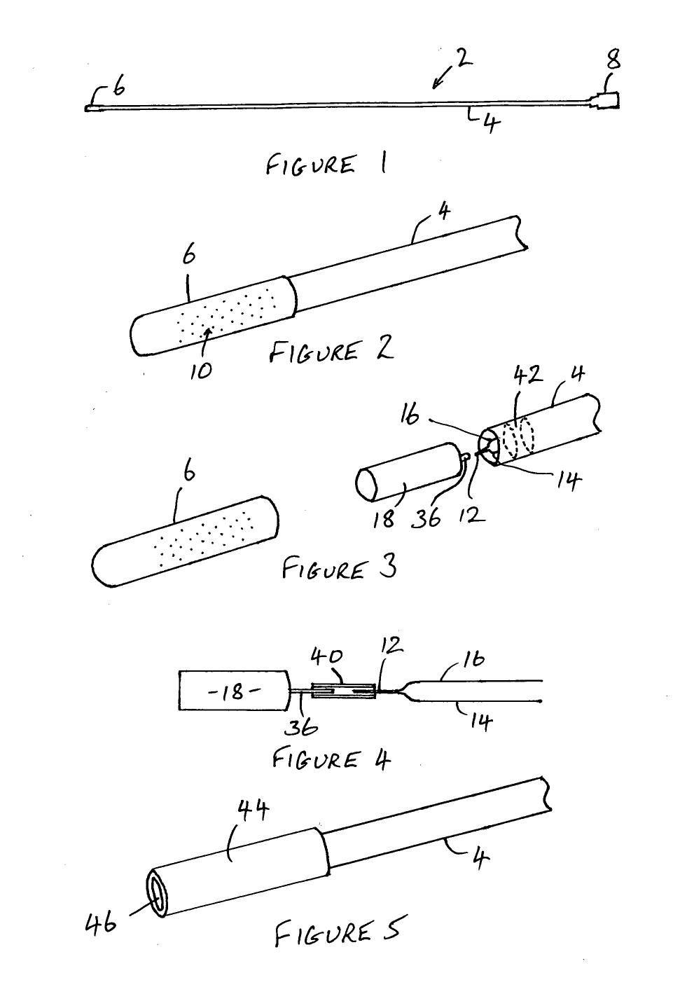

FIG. 4 illustrates a connection between a first contact or electrode wire of the gas concentration sensor and the thermocouple junction of the embodiment of FIG. 3;

FIG. 5 is a perspective view of the tip of a probe according to a second embodiment of the invention;

FIG. 6 is a side view of the tip of a conventional thermocouple probe;

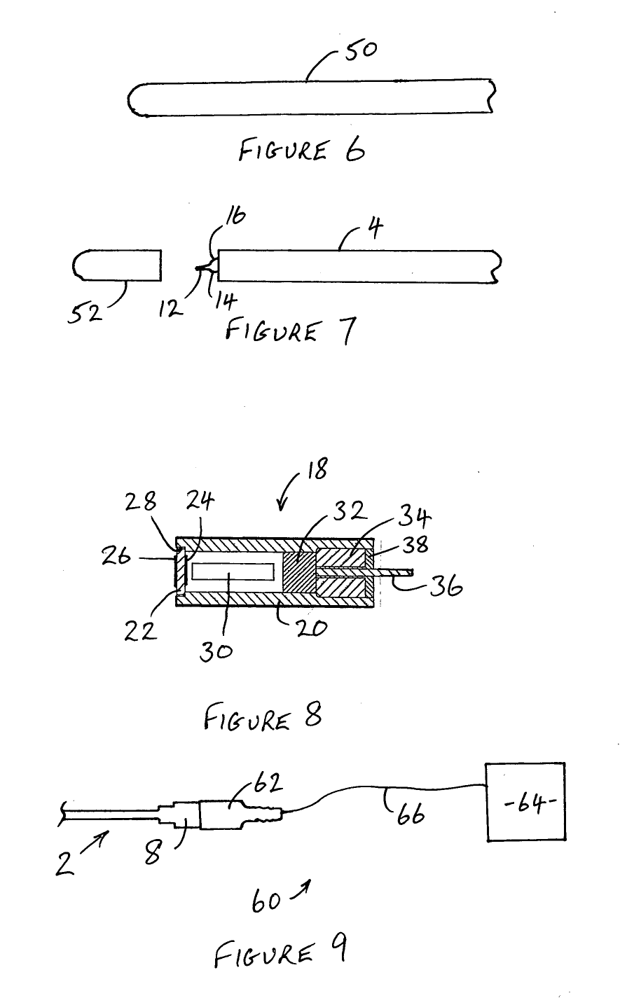

FIG. 7 illustrates the removal of the tip of the thermocouple probe of FIG. 6 to expose the thermocouple junction;

FIG. 8 is a cross-section of a gas-concentration sensor suitable for implementing embodiments of the invention; and

FIG. 9 illustrates a support apparatus and a measurement apparatus embodying a further aspect of the invention.

FIG. 1 shows a probe 2 comprising a long tubular support 4. A cap 6 is secured at a probe end of the tubular support. A probe connection or support apparatus 8 is secured to the opposite end of the tubular support, and provides a means for attaching the probe to further equipment (not shown) both to enable physical handling of the probe during use and electrical connections to the probe for measuring temperature and gas concentration in a fluid medium at elevated temperature, such as a molten metal. In the embodiments described below, reference will be made to measurements of hydrogen concentration in molten metal, by way of example. The invention may provide advantageous performance in measurements of hydrogen concentration in molten metal but is not limited to this application.

FIG. 2 is a magnified view of the probe end of the probe 2. The cap 6 in this embodiment has a rounded, closed end and perforations 10 in its side wall in order to allow diffusion of gas from the molten metal to the interior of the cap, when the probe is immersed in molten metal.

FIG. 3 is an exploded view of the probe tip, showing its components before assembly. A thermocouple extends within the tubular support. The thermocouple junction is positioned near the probe tip and two thermocouple wires extend within the tubular support to the connection apparatus 8. In FIG. 3, the thermocouple junction 12 and parts of the thermocouple wires 14, 16 protrude from the open end of the tubular support 4. A gas concentration sensor 18 is shown in position for connection to the thermocouple junction.

FIG. 8 shows a longitudinal section of the gas concentration sensor 18. This sensor is for the detection of hydrogen gas. It comprises a ceramic tube 20, closed at one end by a planar, proton-conducting, solid-electrolyte disc 22. The disc has a first porous platinum electrode 24 formed on its surface within the tube, and a second porous platinum electrode 26 formed on its surface facing away from the tube. The disc is sealed into a recess in the end of the tube using a silica-free glass 28. A metal-metal hydride reference material 30 is inserted into the tube behind the first electrode (which may be termed the reference electrode) and an electrical conductor (not shown) extends from the first electrode along an internal wall of the tube. A volume within the tube behind the reference material is filled with an inert buffer material 32, such as Y₂O₃ powder. A sensor cap 34 is inserted into the open end of the tube, and secured using a silica-free glass. An electrode wire or contact 36 extends through a hole in the sensor cap and makes contact with the electrical conductor leading to the first electrode 24. The electrode wire is sealed in the hole using a glass seal 38, preferably of a silica-free glass. The solid electrolyte disc, the tube and the sensor cap form the walls of a sensor body enclosing a sealed cavity. The cavity contains the solid reference material, which generates a reference hydrogen partial pressure within the cavity. The electrode wire extends outwardly from the sensor body, coaxial with the tube.

The solid electrolyte is preferably of indium-doped calcium zirconate. The tube and the sensor cap are preferably manufactured from undoped calcium zirconate, in which case the thermal expansion of the tube is matched to that of the electrolyte disc and the sensor cap, allowing the sensor to be thermally cycled without the build up of excessive thermal stresses. Alternatively, the tube and sensor cap can be manufactured from magnesia-magnesium aluminate (MMA), which has a thermal expansion coefficient slightly higher than the indium-doped calcium zirconate electrolyte. In this case, the electrolyte is permanently in a state of compressive stress under measurement conditions (immersed in molten metal), increasing the thermal shock and thermal cycling resistance of the electrolyte. A second electrical conductor (not shown) extends from the second electrode along the outside of the tube 20, to the end of the sensor adjacent to the electrode wire 36.

In use, the second electrode 26 is exposed to a hydrogen concentration to be measured, due to hydrogen diffusing from the molten metal through the perforated or porous cap 6. A difference between the hydrogen partial pressure at the first and second electrodes generates a voltage between the electrodes, from which the unknown hydrogen partial pressure at the second electrode can be obtained.

The reference partial pressure within the sensor cavity varies with the temperature of the sensor. Consequently, it is a significant advantage of probes embodying the invention that the thermocouple can be used to take a temperature reading in close proximity to the gas concentration sensor, which improves the accuracy of gas concentration measurement.

In FIG. 3, the electrode wire or contact 36 is shown prior to connection to the thermocouple. FIG. 4 illustrates one option for connecting the electrode wire 36 to the thermocouple junction 12 by inserting the electrode wire and the thermocouple junction into opposite ends of a metal ferrule 40, and crimping the ferrule. This process has the advantage of avoiding heating the probe components, but other methods such as soldering, applying metal paint (such as platinum ink), brazing or welding may be used, as long as the chosen method is stable at the temperatures to which the probe will be exposed in use.

When the probe is used, it is necessary to allow time for the partial pressure of gas within the probe tip to equilibrate with the partial pressure of the gas in the melt. This occurs by diffusion through the perforated or porous cap, and the time taken for equilibration can be reduced by reducing the volume to be occupied by the gas within the cap. Thus, there may be advantage in sealing the end of the tubular support in order to avoid diffusion of gas within the support. This may be achieved by forming a gas-tight plug 42 (shown in phantom in FIG. 3) near the end of the tubular support. The plug may conveniently be formed by inserting a plug of glass powder into the tubular support and melting the glass to form the plug.

Some conventional thermocouple probes contain compressed mineral powder to serve as an insulator, and ensure electrical insulation between the thermocouple wires and between the wires and the tubular support. A plug 42 may additionally serve to retain the insulator within the tubular support.

FIG. 5 illustrates a further embodiment of the invention. This comprises a tubular support 4 similar to that in FIGS. 1, 2 and 3. The thermocouple and sensor structure of the probe in this embodiment is also the same as in earlier embodiments. However, the cap 44 is fabricated from a ceramic tube, which is secured to the end of the tubular support by means of a suitable bonding agent, such as a glass. The ceramic tube is not porous, but a disc of porous graphite 46 is sealed across the open end of the tube 44. Gas from the metal can diffuse through the porous graphite disc and create a partial pressure of gas for measurement within the probe tip.

It is important that at least the external surfaces of a probe embodying the invention should be sufficiently chemically resistant to the molten metal in which it is to be used. Stainless steel components, for example, may be appropriate for many molten metals, but are not resistant to some molten metals, such as aluminium. For use in aluminium, components made of, for example, stainless steel should be coated to improve their chemical resistance. The appropriate materials selection would be within the capability of the skilled person.

One option for fabricating a probe embodying the invention is to modify a conventional thermocouple probe. The end of such a probe is illustrated in FIG. 6. It comprises a closed-ended tube 50, typically of stainless steel. A thermocouple is housed within the tube, the thermocouple junction being close to the closed end of the tube.

As illustrated in FIG. 7, the end 52 of the thermocouple probe may be cut away to expose the thermocouple junction 12 and the ends of the thermocouple wires 14, 16. The remainder of the thermocouple probe casing may then serve as the tubular support 4 for a probe embodying the invention. A cap as described in earlier embodiments may be fabricated and secured to the end of the tubular support.

In an embodiment of a further aspect of the invention, a monitoring apparatus 60 is provided, as illustrated in FIG. 9. The apparatus comprises a combined handle and electrical socket 62, which plugs into and physically supports the connector end 8 of the probe 2, and a measurement apparatus 64 connected to the handle by means of a lead 66. In use, the combined handle and socket not only supports the probe so that an operator can immerse the probe tip in the molten metal, but also makes contact with electrical connections to the two thermocouple wires and the second electrode. Usually, the connection to the second electrode may be made by means of the tubular support 4, but if appropriate a separate electrical conductor may be employed. The measurement apparatus 64 is electrically connected, by means of the lead 66, to the thermocouple wires and the second electrode and can therefore carry out measurements of temperature and gas concentration as described above.

We claim:

1. A probe for measuring the temperature and gas concentration in a fluid medium, comprising:
a tubular support, a probe end of the support being for contacting, in use, in the fluid medium;
a thermocouple comprising a thermocouple junction and two thermocouple wires extending within the tubular support; and
a gas concentration sensor comprising first and second electrodes;
in which the sensor is supported at the probe end of the tubular support and the first electrode is electrically connected to the thermocouple.

2-16. (canceled)

17. A method for fabricating a probe for measuring the temperature and gas concentration in a fluid medium, comprising the steps of:
electrically connecting a first electrode of a gas concentration sensor comprising first and second electrodes to a thermocouple comprising a thermocouple junction and two thermocouple wires extending within a tubular support; and
supporting the sensor at an end of the tubular support.

18-31. (canceled)
